(19) United States
(12) Patent Application Publication
(10) Pub. No.: US 2012/0223379 A1
(43) Pub. Date: Sep. 6, 2012

(54) NON-VOLATILE MEMORY DEVICES AND METHODS OF MANUFACTURING THE SAME

(76) Inventors: Hyun-Sil OH, Yongin-si (KR); Sung-Hoi Hur, Seoul (KR); Dae-Sin Kim, Yongin-si (KR)

(21) Appl. No.: 13/407,187

(22) Filed: Feb. 28, 2012

(30) Foreign Application Priority Data
Mar. 2, 2011 (KR) 10-2011-0018333

(51) Int. Cl. H01L 27/105; H01L 21/762

(52) U.S. Cl. 257/321; 438/424; 257/E27.081; 257/E21.546

(57) ABSTRACT

A non-volatile memory device includes a substrate including a plurality of active regions and a plurality of device isolating trenches formed between a respective one of each of the active regions along a first direction in the substrate. A plurality of gate structures each including a tunnel insulating layer pattern, a floating gate electrode, a dielectric layer pattern and a control gate electrode is formed on the substrate. A first insulating layer pattern is provided within the device isolating trenches. A second insulating layer pattern is formed along an inner surface portion of a gap between the gate structures. An impurity doped polysilicon pattern is formed on the second insulating layer pattern in the gap between the gate structures.

### CROSS-REFERENCE TO RELATED APPLICATIONS

This application claims priority under 35 USC §119 to Korean Patent Application No. 10-2011-0018333, filed on Mar. 2, 2011, the disclosure of which is hereby incorporated by reference herein in it's entirety.

### TECHNICAL FIELD

Example embodiments relate to non-volatile memory devices and methods of manufacturing the same. More particularly, example embodiments relate to non-volatile memory devices having a decreased coupling ratio and methods of manufacturing the same.

### DESCRIPTION OF THE RELATED ART

As the integration degree of a non-volatile memory device significantly increases, the coupling ratio between neighboring cells may also increase. In addition, a multi-level cell for writing and reading a number of data in one cell has been developed. To accomplish the multi-level cell, a threshold voltage dispersion of each cell transistor may be required to be decreased. However, according to the increase of the coupling ratio between the cells, the threshold voltage dispersion also may be increased. It is further noted that attempting to decrease the coupling ratio and the threshold voltage dispersion may be a difficult task while attempting to increase the integration degree of the non-volatile memory device.

### SUMMARY

Example embodiments provide a non-volatile memory device in which a coupling ratio between cells may be decreased.

Example embodiments provide a method of manufacturing the above-described non-volatile memory device.

According to example embodiments, there is provided a non-volatile memory device. The device includes a substrate including a plurality of active regions and a plurality of device isolating trenches formed between a respective one of each of the active regions along a first direction in the substrate. A plurality of gate structures each including a tunnel insulating layer pattern, a floating gate electrode, a dielectric layer pattern and a control gate electrode formed on the substrate. A first insulating layer pattern is provided within the device isolating trenches. A second insulating layer pattern is formed along an inner surface portion of a gap between the gate structures. An impurity doped polysilicon pattern is formed on the second insulating layer pattern in the gap between the gate structures

In example embodiments, a lower portion of the polysilicon pattern may have a first impurity doped concentration and an upper portion of the polysilicon pattern may have a second impurity doped concentration higher than the first impurity doped concentration.

In example embodiments, a bottom portion of the upper portion of the polysilicon pattern having the second impurity doped concentration may be positioned at a same plane as an upper surface portion of the floating gate electrodes or at a lower plane than the upper surface portion of the floating gate electrodes.

In example embodiments, the bottom portion of the upper portion of the polysilicon pattern having the second impurity doped concentration may be positioned higher than a half of a height of the floating gate electrodes.

In example embodiments, an upper surface portion of the polysilicon pattern may be positioned at a same plane as an upper surface portion of the control gate electrode.

In example embodiments, the polysilicon pattern may completely fill up an inner portion of the gap between the gate structures.

In example embodiments, the polysilicon pattern may fill up a portion of the gap between the gate structures and an air gap may be provided between a bottom portion of the polysilicon pattern and the second insulating layer pattern.

In example embodiments, the polysilicon pattern may have a uniform impurity doped concentration.

In example embodiments, the bottom portion of the polysilicon pattern may be at the same plane as an upper surface portion of the floating gate electrodes or at a lower plane than the upper surface portion of the floating gate electrodes.

According to example embodiments, there is provided a method of manufacturing a non-volatile memory device. In the methods, a plurality of tunnel insulating layer patterns and a plurality of floating gate electrodes are foamed on a substrate. A portion of the substrate between the floating gate electrodes is etched to form a plurality of device isolating trenches in the substrate extending along a first direction. A first insulating layer pattern is formed in the device isolating trenches and a dielectric layer pattern and a control gate electrode are formed on a surface portion of each of the floating gate electrodes. A second dielectric layer pattern is formed along an inner surface portion of a gap between gate structures includes a respective one of each of the tunnel insulating layer patterns, the floating gate electrodes, the dielectric layer patterns and the control gate electrodes. An impurity doped polysilicon pattern is formed on the second insulating layer pattern in the gap between the gate structures.

In example embodiments, the polysilicon pattern may be formed as follows. A polysilicon layer may be formed on the surface portion of the second insulating layer pattern to fill up the gap. The polysilicon layer may be partially removed to form the polysilicon pattern in the gap. Then, impurities may be selectively and highly doped onto the polysilicon pattern.

In example embodiments, the partial removing of the polysilicon layer may be executed using a chemical mechanical polishing process.

In example embodiments, a bottom portion of a region including highly doped impurities in the polysilicon pattern may be at a same plane as an upper surface portion of the floating gate electrodes or at a lower plane than the upper surface portion of the floating gate electrodes.

In example embodiments, the polysilicon pattern may be formed as follows. A polysilicon layer may be formed on the second insulating layer pattern while filling up the gap and doping impurities into the polysilicon layer in situ. Then, the polysilicon layer may be partially removed to faun a polysilicon pattern in the gap.

In example embodiments, the polysilicon pattern may be formed as follows. A polysilicon layer may be formed on the second insulating layer and at only an upper portion of the gap, thereby defining an air gap at a lower portion of the gap. Then, the polysilicon layer may be partially removed to form a polysilicon pattern on the gap.

As described above, a non-volatile memory device may include an impurity doped polysilicon pattern filling up a gap between gate structures in accordance with an example embodiment of the present inventive concept. Through providing the polysilicon pattern in the gap, a coupling ratio between word lines may be decreased. Accordingly, the threshold voltage dispersion of each cell may be decreased. The non-volatile memory device in accordance with example embodiments may have a good electric characteristic.

According to example embodiments, a method of manufacturing a non-volatile memory device is provided. The method includes sequentially forming a preliminary tunnel insulating layer and a floating gate layer on a substrate, etching the preliminary tunnel insulating layer, the floating gate layer and the substrate to form a plurality of preliminary floating gate electrodes having a line shape and a tunnel insulating layer on the substrate and a device isolating trench in the substrate between the preliminary floating gate electrodes. An upper planar surface portion of the substrate excluding the device isolating trench is an active region having a line shape extending in a first direction. The method further includes forming a first insulating layer pattern in the device isolating trench to fill up a first gap between an adjacent pair of the preliminary floating gate electrodes, forming a dielectric layer pattern along a surface portion of the first insulation layer pattern and the preliminary floating gate electrodes, forming a conductive layer on the dielectric layer, partially etching the conductive layer, the dielectric layer, the preliminary floating gate electrodes, the tunnel insulating layer and the first insulating layer pattern to form a plurality of gate structures having a second gap therebetween. Each of the gate structures includes a tunnel insulating layer pattern, a floating gate electrode, a dielectric layer pattern and a control gate electrode sequentially stacked on the substrate.

The method further includes forming a second insulating layer along an inner surface portion of the second gap between the gate structures, forming a polysilicon layer on the second insulating layer and filling up at least a portion of the second gap between the gate structures, removing a portion of the polysilicon layer and the second insulating layer to expose an upper portion of the control gate electrodes of the gate structures, thereby forming a second insulating layer pattern having a U-shape along a sidewall and a bottom portion of the second gap and a polysilicon pattern having a line shape extended in a second direction perpendicular to the first direction on the second insulating layer pattern in the second gap.

### BRIEF DESCRIPTION OF THE DRAWINGS

Example embodiments can be more clearly understood from the following detailed description taken in conjunction with the accompanying drawings. FIGS. 1 to 14 represent non-limiting, example embodiments as described herein.

FIG. 1 is a cross-sectional view illustrating a non-volatile memory device in accordance with an example embodiment of the present inventive concept.

FIG. 2 is a perspective view illustrating the non-volatile memory device illustrated in FIG. 1.

FIG. 3 is a circuit diagram of the non-volatile memory device illustrated in FIG. 1.

FIG. 4 illustrates graphs showing a change of a threshold voltage due to a coupling at each one of cell transistors.

FIG. 5 illustrates graphs showing potential data of a floating gate electrode and a polysilicon pattern due to a coupling at each one of cell transistors in the non-volatile memory device illustrated in FIG. 1.

FIG. 6 illustrates applying voltages while operating data reading with respect to each cell.

FIGS. 7 to 11 are perspective views for explaining a method of manufacturing the non-volatile memory device illustrated in FIGS. 1 and 2.

FIG. 12 is a cross-sectional view of a non-volatile memory device in accordance with an example embodiment of the present inventive concept.

FIG. 13 is a perspective view illustrating the non-volatile memory device illustrated in FIG. 12.

FIG. 14 is a perspective view for explaining a method of manufacturing the non-volatile memory device illustrated in FIGS. 12 and 13.

### DETAILED DESCRIPTION OF EXAMPLE EMBODIMENTS

Various example embodiments will be described more fully hereinafter with reference to the accompanying drawings, in which some example embodiments are shown. Example embodiments of the present inventive concept may, however, be embodied in many different forms and should not be construed as limited to example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

Hereinafter, example embodiments on semiconductor devices and methods of manufacturing the semiconductor devices will be explained in detail.

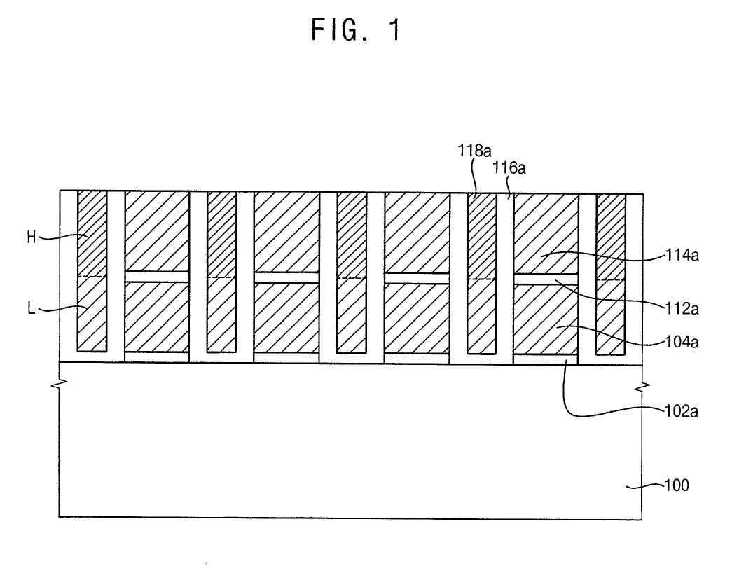

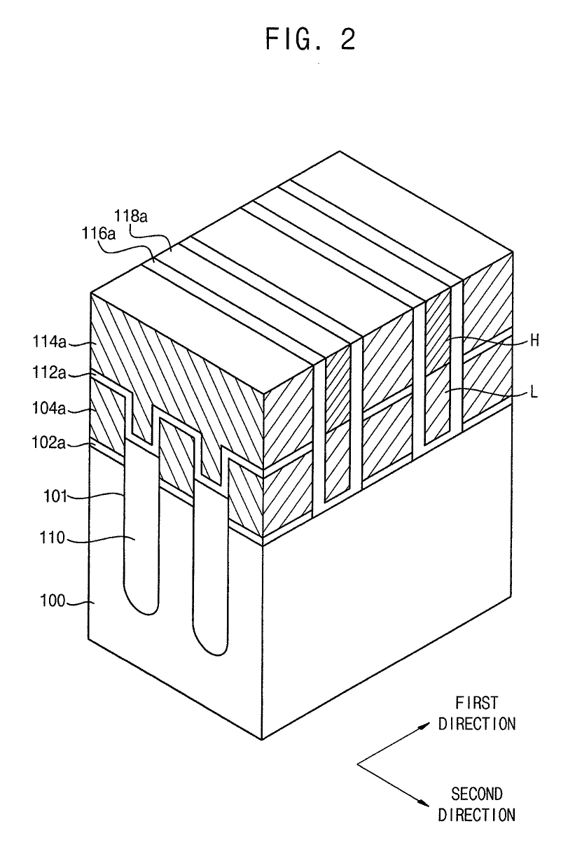

FIG. 1 is a cross-sectional view illustrating a non-volatile memory device in accordance with an example embodiment. FIG. 2 is a perspective view illustrating the non-volatile memory device illustrated in FIG. 1.

Referring to FIGS. 1 and 2, a substrate 100 including, for example, a device isolating trench 101 may be provided. The device isolating trench 101 may be extended in a first direction and may be provided repeatedly. An upper planar portion of the substrate 100 excluding the device isolating trench 101 may become an active region. The active region may have, for example, a line shape extended in the first direction.

On the substrate 100 in the active region, a tunnel insulating layer pattern 102a may be provided. The tunnel insulating layer pattern 102a may be formed using, for example, silicon oxide, an oxynitride compound such as silicon oxynitride, impurity doped silicon oxide, a low dielectric material, etc.

On the tunnel insulating layer pattern 102a, a floating gate electrode 104a may be provided. The floating gate electrode 104a may have, for example, an isolated pattern shape and may be arranged regularly. That is, the floating gate electrode 104a may have, for example, a line shape extended in the first direction and a plurality of the floating gate electrodes 104a may be arranged regularly on the active region. Since one floating gate electrode 104a having an isolated shape may be provided in one memory cell, each of the memory cells may be formed at a position where each of the floating gate electrodes 104 may be formed. The floating gate electrode 104a may be foamed using, for example, polysilicon material.

Within the device isolating trench 101, a first insulating layer pattern 110 may be provided. For example, an upper surface portion of the first insulating layer pattern 110 may be positioned higher than a lower surface portion of the floating gate electrode 104a and higher than an upper surface portion of the tunnel insulating layer pattern 102a. The first insulating layer pattern 110 may include, for example, silicon oxide. The first insulating layer pattern 110 may be provided as a device isolating layer pattern.

On the surface portions of the first insulating layer pattern 110 and the floating gate electrode 104a, a dielectric layer pattern 112a may be provided. The dielectric layer pattern 112a may be extended in a second direction perpendicular to the first direction. The dielectric layer pattern 112a may be formed as, for example, an ONO layer obtained by integrating an oxide layer, a nitride layer and an oxide layer. Alternatively, the dielectric layer pattern 112a may be formed using, for example, a metal oxide having a high dielectricity greater than about 10.

On the dielectric layer pattern 112a, a control gate electrode 114a may be provided. The control gate electrode 114a may fill up a first gap between the floating gate electrodes 114a and may have, for example, a line shape extended in the second direction perpendicular to the first direction. The control gate electrode 114a may include, for example, polysilicon material. Alternatively, the control gate electrode 114a may include, for example, a metal material. The control gate electrode 114a may be used as a word line and thus the reference numeral 114a may be used to refer to a word line as well when the control gate electrode 114a is being used as a word line herein.

Along an inner surface portion of a gap between the control gate electrodes 114a, a second insulating layer pattern 116a may be provided. That is, the second insulating layer pattern 116a may be formed along side walls of the control gate electrode 114a, the dielectric layer pattern 112a and the floating gate electrode 104a and along a bottom surface portion of the substrate 100 disposed within the gap. The second insulating layer pattern 116a may have, for example, a U shape. The second insulating layer pattern 116a may be formed using, for example, silicon oxide.

On the surface of the second insulating layer pattern 116a, a polysilicon pattern 118a completely filling up a gap between the control gate electrodes 114a and a gap between the floating gate electrodes 104a underlying the control gate electrodes 114a may be formed. The polysilicon pattern 118a may be provided in, for example, a floating state without including an electrically connected portion. The polysilicon pattern 118a may have, for example, a line shape extended in the second direction perpendicular to the first direction. The polysilicon pattern 118a may be disposed facing a sidewall of the control gate pattern 114a.

The polysilicon pattern 118a may be doped with impurities. The polysilicon pattern 118a in a region facing the sidewall of the control gate electrode 114a may be, for example, relatively highly doped with the impurities (H). The polysilicon pattern 118a in a region facing the sidewall of the floating gate electrode 104a may be, for example, relatively lightly doped with the impurities (L). For example, the bottom portion of the highly doped impurity region (H) of the polysilicon pattern 118a may be positioned at a same plane as the upper surface portion of the floating gate electrode 104a or at a lower plane than the upper surface portion of the floating gate electrode 104a. In addition, the bottom portion of the highly doped impurity region (H) may be positioned, for example, higher than a bottom portion of the floating gate electrode 104a. For example, the bottom portion of the highly doped impurity region (H) of the polysilicon pattern 118a may be positioned higher than half of a height of the floating gate electrode 104a.

The upper surface portion of the polysilicon pattern 118a may be positioned at, for example, a same plane as the upper surface portion of the control gate electrode 114a.

Hereinafter, a coupling characteristic and a program threshold voltage dispersion characteristic due to the coupling of the non-volatile memory device illustrated in FIG. 1 may be explained.

A cell coupling may be generated as an interfering phenomenon when an interval between cells becomes smaller. The cell coupling may increase the program threshold voltage. The cell coupling may be generated at both directions of a word line direction and a bit line direction. Generally, the cell coupling generated at the word line direction may be a main factor affecting the increase of the program threshold voltage.

The cell coupling may be measured by the following method. In a non-volatile memory device, specific cells may be programmed and an initial program threshold voltage dispersion of cells not affected by adjacent cells may be measured. Then, cell transistors adjacent to each of the programmed cell transistors may be programmed to affect the initially programmed cells to change the initial program threshold voltage dispersion. In this case, a cell coupling may be measured using a difference between the initial program threshold voltage dispersion and the changed threshold voltage dispersion.

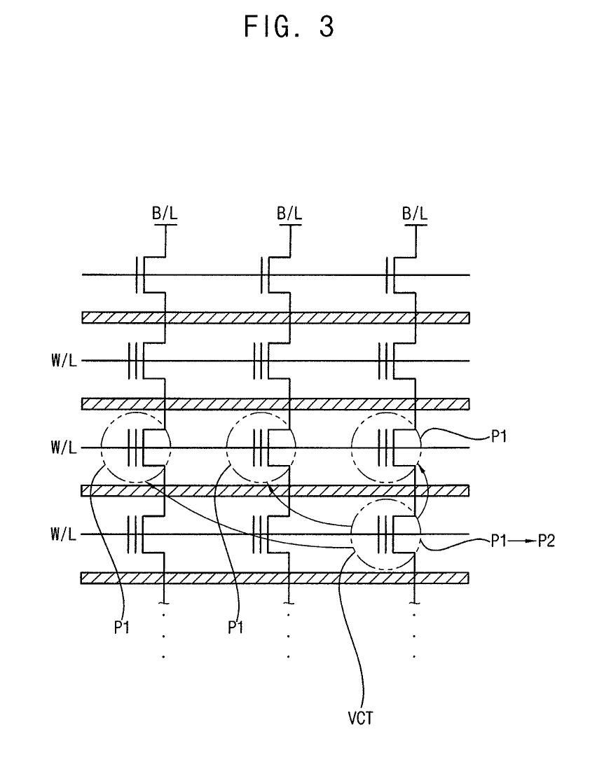

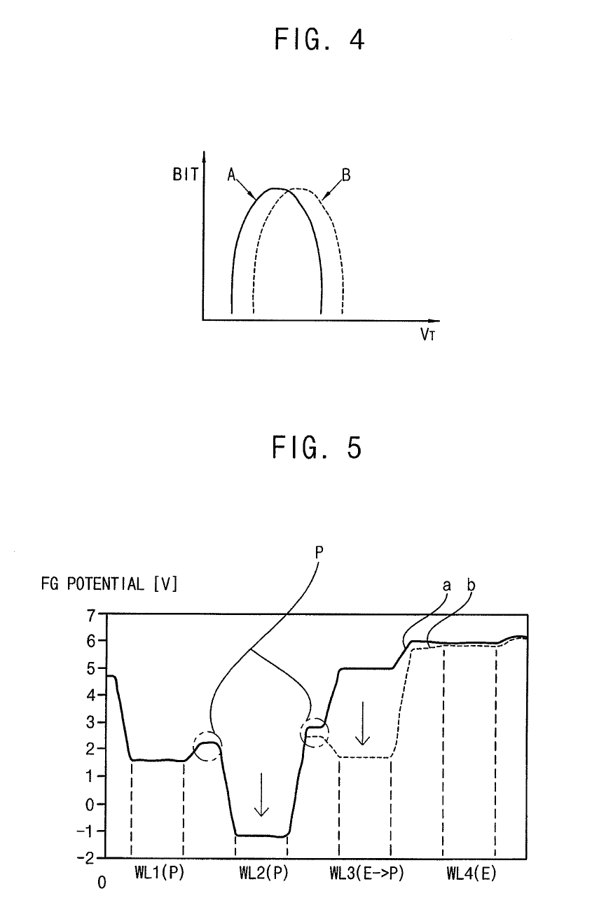

FIG. 3 is a circuit diagram of the non-volatile memory device illustrated in FIG. 1. FIG. 4 illustrates graphs showing a change of a threshold voltage due to a coupling at each one of cell transistors.

As illustrated in FIG. 3, the non-volatile memory device illustrated in FIG. 1 may include a polysilicon pattern facing a word line.

A cell coupling ratio of the non-volatile memory cell may be measured. First, each cell may be firstly programmed (P1) so that the threshold voltage of each cell transistor of the non-volatile memory device may be a first reference voltage. The threshold voltage of each cell transistor at the firstly programmed state may be within a range from the first reference voltage and may show a distribution illustrated by graph A in FIG. 4.

Then, in the non-volatile memory device, a second programming (P2) may be performed so that the threshold voltage of a victim cell transistor (“VCT”) may become a second reference voltage higher than the first reference voltage. Through the second programming (P2), the threshold voltage of other cell transistors adjacent to the victim cell transistor (“VCT”) may also be increased. The threshold voltage of each cell transistor after performing the second programming (P2), may show a distribution illustrated by graph B in FIG. 4.

For non-volatile memory devices having a common structure and excluding a polysilicon pattern, the threshold voltage of the cell transistors adjacent to the victim cell transistor (“VCT”) may be largely increased due to the second programming operation of the victim cell transistor (“VCT”). However, the threshold voltage of the cell transistors (“VCT”) far from the victim cell transistor may not increase much. When performing the second programming operation, the changing of the degree of the threshold voltage of each cell according to position may become large. That is, a large dispersion of the threshold voltage due to the coupling may be generated.

For the non-volatile memory device in accordance with the non-volatile memory device illustrated in FIGS. 1 and 2, a capacitance between the cells due to the polysilicon pattern 118a may be largely increased. Since the polysilicon pattern 118a may have a shape extended along the word line 114a, a capacitance applied to each cell connected to the word line 114a by the polysilicon pattern 118a may become similar. When the second programming operation of the victim cell transistor (“VCT”) is executed, the change of the threshold voltage of neighboring cell transistors may be hardly generated depending on a distance from the victim cell transistor (“VCT”). That is, through performing the second programming (P2) operation, the threshold voltage difference between the cell transistors near the victim cell transistor (“VCT”) and the cell transistors far from the victim cell transistor (“VCT”) may be small. The non-volatile memory device in accordance with the non-volatile memory device illustrated in FIGS. 1 and 2 may generate little threshold voltage dispersion due to the coupling.

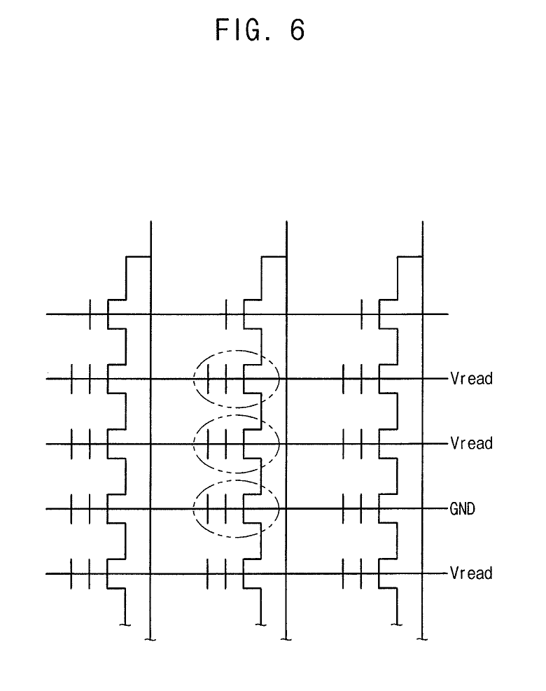

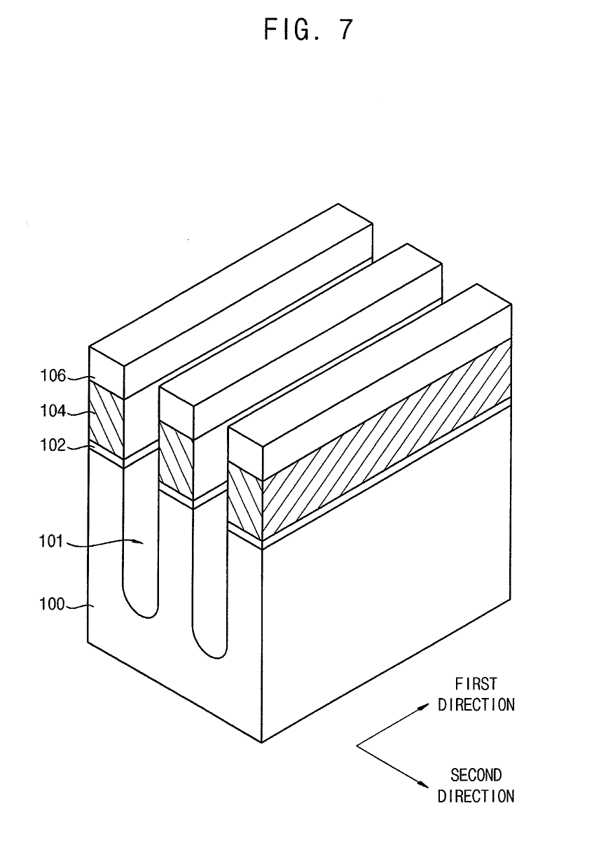

FIG. 5 illustrates graphs showing potential data of a floating gate electrode and a polysilicon pattern due to a coupling at each one of cell transistors in the non-volatile memory device illustrated in FIG. 1. FIG. 6 illustrates applying voltages while operating data reading with respect to each cell.

Referring to FIG. 5, designated graph “a” represents a potential of a floating gate electrode 104a and a polysilicon pattern 118a in a cell transistor when initial data is written, respectively.

Designated graph “b” represents a potential of a floating gate electrode 104a and a polysilicon pattern 118a of each cell transistor after programming a victim cell transistor (“VCT”).

Referring to FIG. 6, a reading voltage (Vread) may be applied to the word lines 114a neighboring a cell to be read while reading written data in the cell. The voltage of the polysilicon pattern 118a disposed between the word lines 114a may be somewhat increased by the applied reading voltage. It is further noted that as shown FIG. 6, a ground voltage (“GND”) may be applied to word lines which are not to be read. After executing the programming operation and reading the written data from each cell transistor, the potential of each polysilicon pattern 118a may be increased (designated by “P” portion) as illustrated in FIG. 5.

When the voltage of the polysilicon pattern 118a increases, the threshold voltage increasing phenomenon may be relaxed after the coupling. Since the impurities may be highly doped into the polysilicon pattern 118a between the word lines, the voltage of the polysilicon pattern 118a may become greater from the reading voltage. So, the coupling may be decreased by the word line and the coupling dispersion may be decreased.

When the cell to be read and a neighboring cell are programmed, the voltage of the polysilicon pattern 118a may be lowered due to the programmed floating gate electrode 104a. When the voltage of the polysilicon pattern 118a is lowered, the increase in the threshold voltage due to the coupling may not be restrained. Since the polysilicon pattern facing the floating gate electrode 104a may be lightly doped by impurities, the voltage change of the polysilicon pattern 118a due to the programmed floating gate electrode 104a may decrease.

As described above, polysilicon patterns having different impurity concentrations may be disposed in accordance with positions in the non-volatile memory device in accordance with example embodiments. Accordingly, the coupling may decrease and the dispersion decreasing effect may be high.

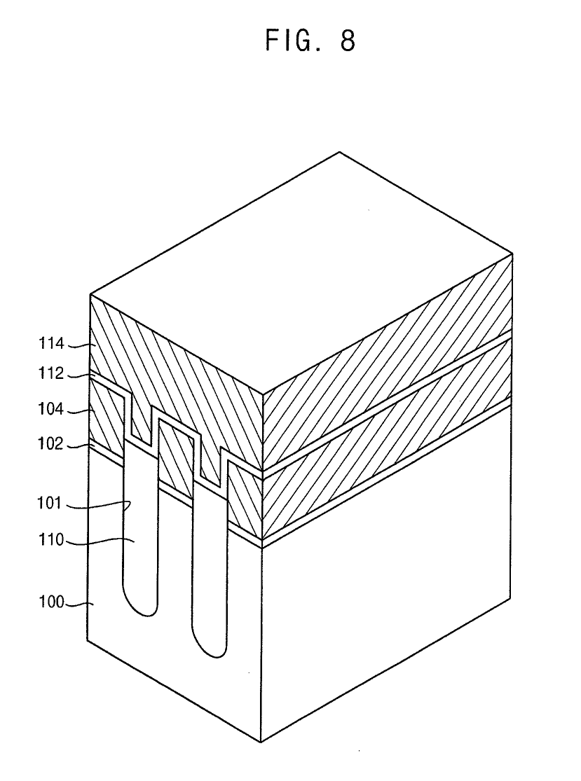

FIGS. 7 to 11 are perspective views for explaining a method of manufacturing the non-volatile memory device illustrated in FIGS. 1 and 2.

Referring to FIG. 7, a preliminary tunnel insulating layer and a floating gate layer may be subsequently formed on a semiconductor substrate 100 including, for example, a single crystalline silicon. The preliminary tunnel insulating layer may be formed through, for example, a thermal oxidation of the semiconductor substrate 100. The floating gate layer may be formed by, for example, depositing polysilicon so as to store and release charges.

On the floating gate layer, a first mask pattern 106 may be formed. The first mask pattern 106 may be a mask for forming a device isolating trench and may have, for example, a line shape extended in the first direction. The first mask pattern 106 may be, for example, a photoresist pattern or a hard mask pattern.

The floating gate layer, the preliminary tunnel insulating layer and the substrate 100 may be etched one by one using the first mask pattern 106. A preliminary floating gate electrode 104 having, for example, a line shape and a tunnel insulating layer 102 may be formed on the substrate 100 and a device isolating trench 101 may be formed in the substrate 100. An upper planar surface portion of the substrate 100 excluding the device isolating trench 101 may become an active region.

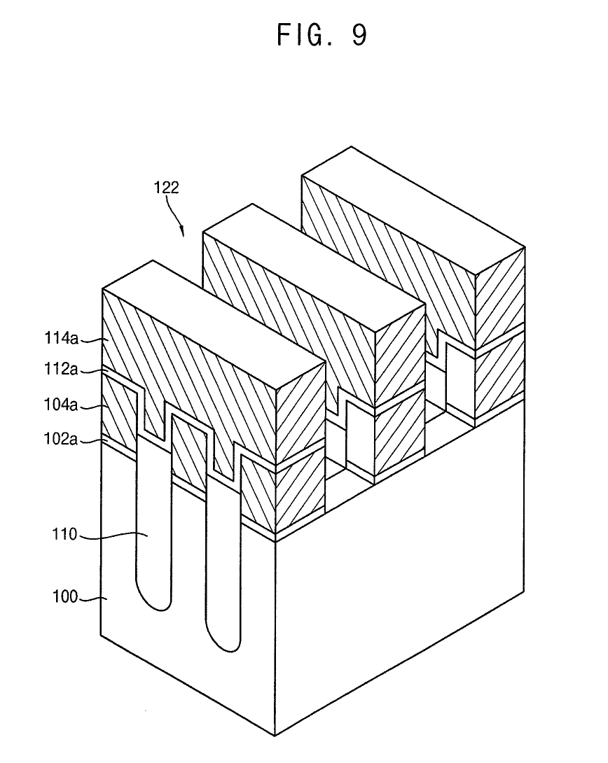

Referring to FIG. 8, a first insulting layer (not illustrated) filling up a gap portion between the device isolating trench 101 and the preliminary floating gate electrode 104 is formed. The first insulating layer may be polished to expose an upper surface portion of the first mask pattern 106. A preliminary first insulating layer pattern (not illustrated) may be formed in a gap between the device isolating trench 101 and the preliminary floating gate electrode 104. Then, the first mask pattern 106 may be removed.

The upper portion of the preliminary first insulating layer pattern may be partially etched to form a first insulating layer pattern 110. The upper surface portion of the first insulating layer pattern 110 may be, for example, positioned higher than the upper surface portion of the tunnel insulating layer 102. Then, the sidewall and the upper surface portions of the preliminary floating gate electrode 104 may be exposed.

A dielectric layer 112 may be formed along the surface portion of the first insulating layer pattern 110 and the preliminary floating gate electrode 104. The dielectric layer 112 may be formed by, for example, integrating silicon oxide, silicon nitride and silicon oxide one by one. Alternatively, the dielectric layer 112 may be formed by, for example, depositing a metal oxide having a dielectric constant greater than about 10.

A conductive layer 114 may be formed on the dielectric layer 112. The conductive layer 114 may include, for example, polysilicon or a metal material.

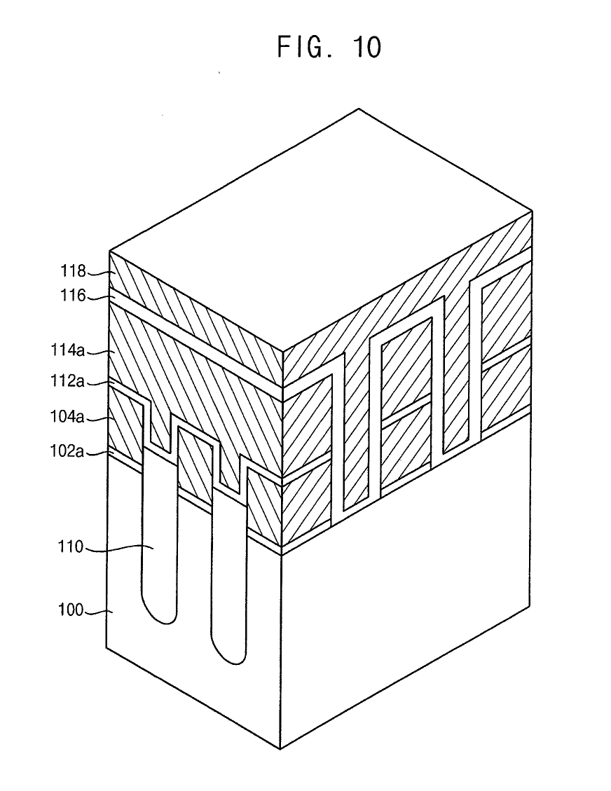

Referring to FIG. 9, a second mask pattern (not illustrated) may be formed on the conductive layer 114. The second mask pattern may be provided as an etching mask for forming a control gate electrode. The second mask pattern may have, for example, a line shape extended in the second direction perpendicular to the first direction.

The conductive layer 114, the dielectric layer 112, the preliminary floating gate electrode 104, the tunnel insulating layer 102 and the first insulating layer pattern 110 may be partially etched one by one using the second mask pattern as an etching mask. A structure including a tunnel insulating layer pattern 102a, a floating gate electrode 104a, a dielectric layer pattern 112a and a control gate electrode 114a may be formed. A gap 122 may be formed between the structures. For example, the floating gate electrode 104a may have an isolated pattern shape and may be arranged regularly along the upper surface portion of the substrate in the active region.

Referring to FIG. 10, a second insulating layer 116 may be formed along an inner surface portion of the gaps 122 between the structures. The inner width of the gap 122 may decrease due to the second insulating layer 116. A polysilicon layer 118 completely filling up the inner portion of the gap 122 may be formed on the second insulating layer 116. The polysilicon layer 118 may be lightly doped through, for example, an in-situ doping process.

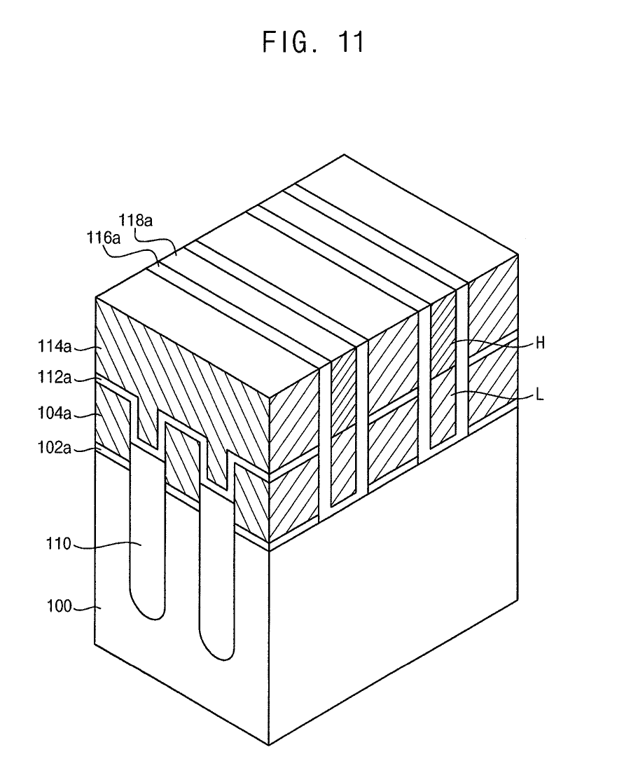

Referring to FIG. 11, the polysilicon layer 118 and the second insulating layer 116 may be partially removed to expose the upper surface portion of the control gate electrode 114a. The removal may be performed through, for example, a chemical mechanical polishing process. Then, a polysilicon pattern 118a and a second insulating layer pattern 116a may be formed. The second insulating layer pattern 116a may have, for example, a U shape along a sidewall and a bottom portion of the gap. In addition, the polysilicon pattern 118a may have, for example, a line shape extended in the second direction perpendicular to the first direction. The upper surface portion of the polysilicon pattern 118a may have, for example, substantially the same height as the upper surface portion of the control gate electrode 114a.

A doping process may be performed so as to highly dope impurities into a region of the polysilicon pattern 118a facing the sidewall of the control gate electrode 114a. Through performing the doping process, the upper portion of the polysilicon pattern 118a may become, for example, a highly doped impurity region (H) and the lower portion of the polysilicon pattern 118a may become a lightly doped impurity region (L). Alternatively, for example, only the upper portion of the polysilicon layer 118 may be highly doped in-situ while performing a deposition process of the polysilicon layer 118.

The bottom portion of the highly doped impurity region (H) in the polysilicon pattern 118a may be positioned, for example, at a same plane as the upper surface portion of the floating gate electrode 104a or at a lower plane than the upper surface portion of the floating gate electrode 104a. In addition, the bottom portion of the highly doped impurity region (H) may be, for example, higher than the bottom portion of the floating gate electrode 104a. For example, the bottom portion of the highly doped impurity region (H) may be positioned higher than half of the height of the floating gate electrode 104a.

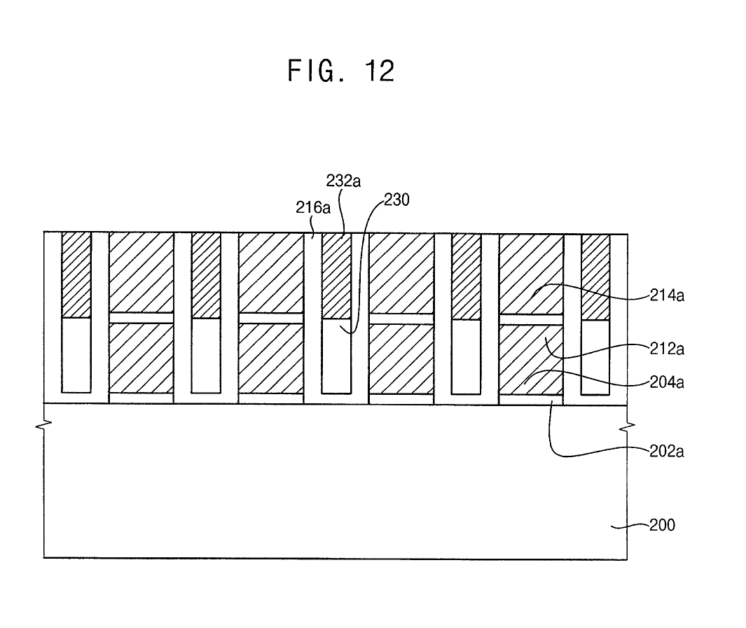

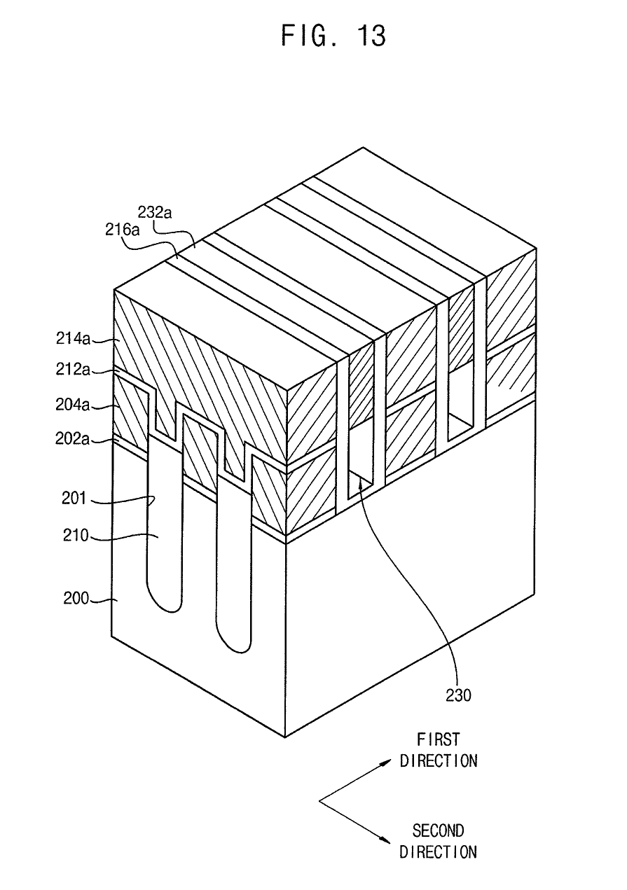

FIG. 12 is a cross-sectional view of a non-volatile memory device in accordance with an example embodiment of the present inventive concept. FIG. 13 is a perspective view illustrating the non-volatile memory device illustrated in FIG. 12. The non-volatile memory device in FIGS. 12 and 13 may have the same structure as the non-volatile memory device illustrated in FIGS. 1 and 2 except for the shape of the polysilicon pattern.

Referring to FIGS. 12 and 13, a substrate 200 including, for example, a device isolating trench 201 may be provided. A first insulating layer pattern 210 may be provided within the device isolating trench 201. A tunnel insulating layer pattern 202a, a floating gate electrode 204a, a dielectric layer pattern 212a and a control gate electrode 214a may be provided on the substrate 200 similar to the non-volatile memory device illustrated in FIGS. 1 and 2.

A second insulating layer pattern 216a may be formed along the surface portion of a gap between the control gate electrodes 214a. The second insulating layer pattern 216a may have, for example, a U shape along the surface portion of the gap. The second insulating layer pattern 216a may be formed using, for example, silicon oxide.

On the second insulating layer pattern 216a, a polysilicon pattern 232a may be provided within the gap between the control gate electrodes 214a. The polysilicon pattern 232a may be, for example, highly doped with impurities.

The bottom portion of the polysilicon pattern 232a may not make a contact with the second insulating layer pattern 216a. That is, the bottom portion of the polysilicon pattern 232a may be positioned at, for example, the same plane as the upper surface portion of the floating gate electrode 204a or at a lower plane than the upper surface portion of the floating gate electrode 204a. In addition, the bottom portion of the polysilicon pattern 232a may be positioned, for example, higher than the second insulating layer pattern 216a.

Between the bottom portion of the polysilicon pattern 232a and the second insulating layer pattern 216a, an air gap 230 may be formed. The air gap 230 may be positioned facing the sidewall of the floating gate electrode 204a.

The polysilicon pattern 232a may be, for example, in a floating state without including an electrically connected portion. The polysilicon pattern 232a may have, for example, a line shape extended in the second direction perpendicular to the first direction. The polysilicon pattern 232a may be positioned facing the sidewall of the control gate electrode 214a.

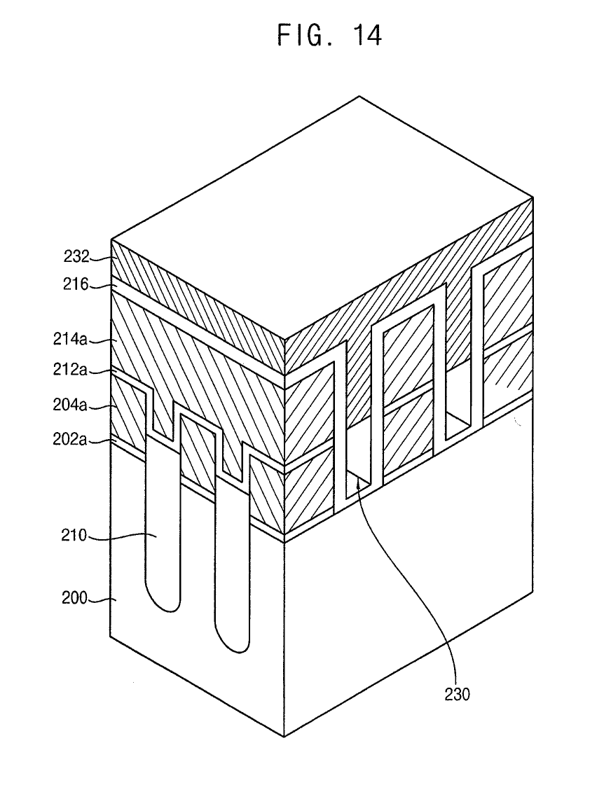

FIG. 14 is a perspective view for explaining a method of manufacturing the non-volatile memory device illustrated in FIGS. 12 and 13.

The method of manufacturing the non-volatile memory device in FIGS. 12 and 13 may be similar to the method of manufacturing the non-volatile memory device in FIGS. 1 and 2 except for the shape of a polysilicon pattern.

The structure illustrated in FIG. 9 may be formed through executing the same processes described referring to FIGS. 7 to 9.

Referring to FIG. 14, a second insulating layer 216 may be formed along an inner surface portion of a gap between the structures. The width of the gap may be decreased through forming the second insulating layer 216.

On the second insulating layer 216, a polysilicon layer 232 filing up a portion of an upper portion of the gap may be formed. Since the width of the gap may be small, the polysilicon layer may not be deposited to the bottom portion of the gap. In this case, the bottom portion of the polysilicon layer 232 may not make contact with the second insulating layer 216. That is, an air gap 230 may be formed between the bottom portion of the polysilicon layer 232 and the second insulating layer 216.

The bottom portion of the polysilicon layer 232 facing the upper surface portion of the second insulating layer 216 may be positioned at, for example, the same plane as the upper surface portion of the floating gate electrode 204a or at a lower position than the upper surface portion of the floating gate electrode 204a. For example, the bottom portion of the polysilicon layer 232 may be positioned higher than half of the height of the floating gate electrode 204a.

The polysilicon layer 232 may be, for example, highly doped with impurities. Alternatively, the polysilicon layer 232 may be, for example, highly doped with impurities in-situ while depositing the polysilicon layer 232 without performing a separate doping process.

Referring to FIG. 13 again, the polysilicon layer 232 and the second insulating layer 216 may be chemically and mechanically polished to expose the upper surface portion of the control gate electrode 214a. Then, a polysilicon pattern 232a and a second insulating layer pattern 216a may be formed. The second insulating layer pattern 216a may have, for example, a U shape along the sidewall and the bottom portion of the gap. In addition, the polysilicon pattern 232a may have, for example, a line shape extended in the second direction perpendicular to the first direction. The upper surface portion of the polysilicon pattern 232a may have, for example, substantially the same height as the upper surface portion of the control gate electrode 214a.

Hereinafter, the coupling and programming rate of the non-volatile memory device in accordance with an example embodiment and a non-volatile memory device having a common structure may be compared.

### Experiment on Coupling

A first programming may be executed with respect to a victim cell and seven cells near the victim cell so that a threshold voltage may be a first reference voltage. The number of the object cells executing the first programming may be changed. The first reference voltage may be set to 1 V in this experiment. After operating the first programming, the threshold voltage of each cell may be measured.

A second programming may be executed with respect to only the victim cell so that the threshold voltage may be a second reference voltage. The second reference voltage may be higher than the first reference voltage. In this experiment, the second reference voltage may be about 5V, which may be higher than the first reference voltage by about 4V. After executing the second programming with respect to the victim cell, the threshold voltage of each cell may be measured again. Effects on the threshold voltage of the seven cells near the victim cell due to the programming operation with respect to the victim cell may be evaluated. The changed threshold voltage after executing the second programming may be called a coupling value. The data concerning the programming operation and the threshold voltage are simulated data.

A non-volatile memory device of example sample #1 including a structure having the polysilicon pattern in accordance with the non-volatile memory device of FIGS. 1 and 2 was manufactured. The experiment on the coupling explained above was executed with respect to the non-volatile memory device of example sample #1. In addition, a programming rate of the non-volatile memory device of example sample #1 was evaluated.

A non-volatile memory device of example sample #2 including a structure having the polysilicon pattern in accordance with the non-volatile memory device of FIGS. 12 and 13 was manufactured. The experiment on the coupling explained above was executed with respect to the non-volatile memory device of example sample #2. In addition, a programming rate of the non-volatile memory device of example sample #2 was evaluated.

A non-volatile memory device of comparative sample #1 including a structure having a highly and entirely doped polysilicon pattern with impurities was manufactured. The polysilicon pattern may have the same shape as the polysilicon pattern illustrated in the non-volatile memory device of FIGS. 1 and 2. The experiment on the coupling explained above was executed with respect to the non-volatile memory device of comparative sample #1. In addition, a programming rate of the non-volatile memory device of comparative sample #1 was evaluated.

A non-volatile memory device of comparative sample #2 including a structure having an air gap between word lines was manufactured. The non-volatile memory device of comparative sample #2 may not include a polysilicon pattern. The experiment on the coupling explained above was executed with respect to the non-volatile memory device of comparative sample #2. In addition, a programming rate of the non-volatile memory device of comparative sample #2 was evaluated.

The experimental results are illustrated in Table 1.

TABLE 1

| | | | Comparative | Comparative |
|---|---|---|---|---|
| | Sample #1 | Sample #2 | sample #1 | sample #2 |
| Word line | 0.26 V | 0.44 V | 0.26 V | 0.46 V |
| coupling | | | | |
| Programming | 21 sec | 20.6 sec | 22.5 sec | 20.6 sec |
| rate | | | | |

When comparing example sample #1 including the polysilicon pattern having different concentrations in the upper and lower doping portions, with comparative sample #1 including the highly doped polysilicon pattern, the programming rate of example sample #1 is illustrated as being faster than the programming rate of comparative sample #1.

Further, when comparing example sample #2 including the polysilicon pattern at the upper portion and including the air gap at the lower portion, with comparative sample #2 including only the air gap between the word lines, the coupling between the word lines is illustrated as being smaller for example sample #2 than for comparative sample #2.

As described above, a non-volatile memory device in accordance with example embodiments may have good operating characteristics. The non-volatile memory device of example embodiments may be applied to various electronic appliances including, for example, a memory card, a digital camera, a storing medium, etc.

Having described example embodiments of the present inventive concept, it is further noted that it is readily apparent to those of reasonable skill in the art that various modifications may be made without departing from the spirit and scope of the invention which is defined by the metes and bounds of the appended claims.

What is claimed is:

1. A non-volatile memory device comprising:
a substrate including a plurality of active regions and a plurality of device isolating trenches formed between a respective one of each of the active regions along a first direction in the substrate;
a plurality of gate structures each including a tunnel insulating layer pattern, a floating gate electrode, a dielectric layer pattern and a control gate electrode formed on the substrate;
a first insulating layer pattern provided within the device isolating trenches;
a second insulating layer pattern formed along an inner surface portion of a gap between the gate structures; and
an impurity doped polysilicon pattern formed on the second insulating layer pattern in the gap between the gate structures.

2. The non-volatile memory device of claim 1, wherein a lower portion of the polysilicon pattern has a first impurity doped concentration and an upper portion of the polysilicon pattern has a second impurity doped concentration higher than the first impurity doped concentration.

3. The non-volatile memory device of claim 2, wherein a bottom portion of the upper portion of the polysilicon pattern having the second impurity doped concentration is positioned at a same plane as an upper surface portion of the floating gate electrodes or at a lower plane than the upper surface portion of the floating gate electrodes.

4. The non-volatile memory device of claim 3, wherein the bottom portion of the upper portion of the polysilicon pattern having the second impurity doped concentration is positioned higher than a half of a height of the floating gate electrodes.

5. The non-volatile memory device of claim 1, wherein an upper surface portion of the polysilicon pattern is positioned at a same plane as an upper surface portion of the control gate electrodes.

6. The non-volatile memory device of claim 1, wherein the polysilicon pattern completely fills up an inner portion of the gap between the gate structures.

7. The non-volatile memory device of claim 1, wherein the polysilicon pattern fills up a portion of the gap between the gate structures and an air gap is provided between a bottom portion of the polysilicon pattern and the second insulating layer pattern.

8. The non-volatile memory device of claim 7, wherein the polysilicon pattern has a uniform impurity doped concentration.

9. The non-volatile memory device of claim 7, wherein the bottom portion of the polysilicon pattern is at a same plane as an upper surface portion of the floating gate electrodes or at a lower plane than the upper surface portion of the floating gate electrodes.

10. A method of manufacturing a non-volatile memory device comprising:
forming a plurality of tunnel insulating layer patterns and a plurality of floating gate electrodes on a substrate;
etching a portion of the substrate between the floating gate electrodes to form a plurality of device isolating trenches in the substrate extending along a first direction;
forming a first insulating layer pattern in the device isolating trenches;
forming a dielectric layer pattern and a control gate electrode on a surface portion of each of the floating gate electrodes;
forming a second insulating layer pattern along an inner surface portion of a gap between gate structures each including a respective one of each of the tunnel insulating layer patterns, the floating gate electrodes, the dielectric layer patterns and the control gate electrodes; and
forming an impurity doped polysilicon pattern on the second insulating layer pattern in the gap between the gate structures.

11. The method of claim 10, wherein the forming of the polysilicon pattern comprises:
forming a polysilicon layer on a surface portion of the second insulating layer pattern to fill up the gap;
partially removing the polysilicon layer to form the polysilicon pattern in the gap; and
selectively and highly doping impurities onto the polysilicon pattern.

12. The method of claim 11, wherein the partial removing of the polysilicon layer is executed using a chemical mechanical polishing process.

13. The method of claim 11, wherein a bottom portion of a region including highly doped impurities in the polysilicon pattern is at a same plane as an upper surface portion of the floating gate electrodes or at a lower plane than the upper surface portion of the floating gate electrodes.

14. The method of claim 10, wherein the forming of the polysilicon pattern comprises:
forming a polysilicon layer on the second insulating layer pattern while filling up the gap and doping impurities into the polysilicon layer in situ; and
partially removing the polysilicon layer to form a polysilicon pattern in the gap.

15. The method of claim 10, wherein the forming of the polysilicon pattern comprises:
forming a polysilicon layer on the second insulating layer and at only an upper portion of the gap, thereby defining an air gap at a lower portion of the gap; and
partially removing the polysilicon layer to form a polysilicon pattern on the gap.

16. A method of manufacturing a non-volatile memory device comprising:
sequentially forming a preliminary tunnel insulating layer and a floating gate layer on a substrate;
etching the preliminary tunnel insulating layer, the floating gate layer and the substrate to form a plurality of preliminary floating gate electrodes having a line shape and a tunnel insulating layer on the substrate and a device isolating trench in the substrate between the preliminary floating gate electrodes, wherein an upper planar surface portion of the substrate excluding the device isolating trench is an active region having a line shape extending in a first direction forming a first insulating layer pattern in the device isolating trench to fill up a first gap between an adjacent pair of the preliminary floating gate electrodes;
forming a dielectric layer pattern along a surface portion of the first insulation layer pattern and the preliminary floating gate electrodes;
forming a conductive layer on the dielectric layer;
partially etching the conductive layer, the dielectric layer, the preliminary floating gate electrodes, the tunnel insulating layer and the first insulating layer pattern to form a plurality of gate structures having a second gap therebetween, wherein each of the gate structures includes a tunnel insulating layer pattern, a floating gate electrode, a dielectric layer pattern and a control gate electrode sequentially stacked on the substrate;
forming a second insulating layer along an inner surface portion of the second gap between the gate structures;
forming a polysilicon layer on the second insulating layer and filling up at least a portion of the second gap between the gate structures;
removing a portion of the polysilicon layer and the second insulating layer to expose an upper portion of the control gate electrodes of the gate structures, thereby forming a second insulating layer pattern having a U-shape along a sidewall and a bottom portion of the second gap and a polysilicon pattern having a line shape extended in a second direction perpendicular to the first direction on the second insulating layer pattern in the second gap.

17. The method of claim 16, wherein the polysilicon pattern is formed on the second insulating layer partially filling an upper portion of the second gap, thereby defining an air gap located in a lower portion of the second gap between a bottom portion of the polysilicon pattern and an upper portion of the second insulating layer pattern and wherein the air gap is positioned facing a sidewall of the floating gate electrodes.

18. The method of claim 16, wherein the polysilicon pattern is formed on the second insulating layer pattern completely filling the second gap and wherein the polysilicon pattern makes direct physical contact with a portion of the second insulating layer pattern formed on the bottom portion of the second gap.

19. The method of claim 18, wherein the polysilicon layer is lightly doped prior to forming the polysilicon pattern and a doping process is performed on the polysilicon pattern such that the polysilicon pattern has an upper portion including a highly doped impurity region and a lower portion including a lightly doped impurity region.

20. The method of claim 16, wherein each of the floating gate electrodes is formed having an isolated pattern shape and arranged regularly along the upper planar surface portion of the substrate in the active region, wherein the dielectric layer pattern extends in the second direction perpendicular to the first direction, and wherein the control gates have a line shape extending in the second direction perpendicular to the first direction.
